(19) United States
(12) Patent Application Publication
(10) Pub. No.: US 2012/0137971 A1
(43) Pub. Date: Jun. 7, 2012

(54) HYDROPHOBIC PROPERTY ALTERATION USING ION IMPLANTATION

(75) Inventors: Patrick M. MARTIN, Ipswich, MA (US); Ludovic Godet, Boston, MA (US)

(73) Assignee: VANRIAN SEMICONDUCTOR EQUIPMENT ASSOCIATES, INC., Gloucester, MA (US)

(21) Appl. No.: 12/973,057

(22) Filed: Dec. 20, 2010

Related U.S. Application Data
(60) Provisional application No. 61/419,548, filed on Dec. 3, 2010.

(51) Int. Cl. B05C 21/00; H01L 33/00; H01L 21/425; C23C 14/48

(52) U.S. Cl. 118/504; 427/526; 438/45; 438/514; 427/2.11; 257/E33.001; 257/E21.473

(57) ABSTRACT

A template used for printing is implanted to change the properties of the materials it is composed of. This template may have multiple surfaces that define indentations. The ion species that is implanted may be C, N, H, F, He, Ar, B, As, P, Ge, Ga, Si, Zn, and Al and is configured to render the implanted regions hydrophobic in one instance. This will reduce adhesion of a polymer to the template during a printing process. The implant may be at a plurality of angles so all surfaces of the template are implanted. In other instances, a film on the surface of the template is knocked in or hardened using the ion species.

### CROSS-REFERENCE TO RELATED APPLICATIONS

This claims priority to the provisional patent application entitled “Hydrophobic Property Alteration Using Ion Implantation,” filed Dec. 3, 2010 and assigned U.S. App. No. 61/419,548, the disclosure of which is hereby incorporated by reference.

### FIELD

This invention relates to implantation to affect properties of materials and, more particularly, to implantation to affect properties of templates used for printing.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the beam penetrate into the bulk of the workpiece material and are embedded into the lattice of the workpiece material to form an implanted region.

Imprint or nano-imprint technology is a known method to form a pattern on a workpiece. A polymer is dispensed on a workpiece and a template is used to transform the polymer into the desired pattern. This desired pattern may be, for example, lines or stripes across the workpiece. The same template may be used multiple times to form a pattern across a surface of a single workpiece.

FIG. 1 is a cross-sectional view of printing using a template during a first step. The template 100 is positioned above a workpiece 105 with a polymer 101 in between. The polymer may be, for example, a photoresist, though other polymers are possible. In this particular embodiment, the template 100 has multiple indentations 109 with a width 103 and depth 102. For example, the width 103 may be approximately 30 nm and the depth 102 may be approximately 60 nm. The indentations 109 may vary in exact shape, width, or depth depending on the desired pattern of the polymer 101. The polymer 101 enters these indentations 109 and is exposed to a wavelength 104, which may be UV light. In one instance the wavelength 104 is approximately 365 nm. This hardens the polymer 101 into a shape that mirrors the indentations 109 in the template 100.

FIG. 2 is a cross-sectional view of printing using a template during a second step. The template 100 is separated from the workpiece 105. However, the polymer 101 may adhere to the template 100. This polymer 101 is composed of C, O, and H atoms, so polar H atoms may be attracted to the template 100. However, there may be other mechanisms that cause the polymer 101 to adhere to the template 100 and the embodiments disclosed herein are not limited to any one mechanism.

The pattern 106 of the polymer 101 is desired and approximately matches the width 103 and depth 102 seen in FIG. 1. However, if the polymer 101 adheres or sticks to the template 100, then the pattern 107 or pattern 108 illustrated in FIG. 2 may be formed. The pattern 107 is elongated compared to the pattern 106 at least partly because the polymer 101 adhered to the template 100. The pattern 108 has less fidelity and is the incorrect shape when compared to pattern 106 because part of the polymer 101 broke off and remains in the indentation 109 of the template 100 at least partly because the polymer 101 adhered to the template 100. If the patterns formed using the template are not accurate or are the wrong dimension, further processing steps may be performed incorrectly. This may lead to more scrapped workpieces and increased production costs. Accordingly, there is a need in the art for an implantation method that affects properties of material and, more particularly, an implantation method that affects properties of templates used for printing.

### SUMMARY

According to a first aspect of the invention, a method of implanting is provided. The method comprises implanting at least one surface of a template with an ion species. This template is configured for printing. A material is printed on a workpiece using the template.

According to a second aspect of the invention, a template apparatus is provided. The template apparatus comprises a template composed of silica having a plurality of surfaces. These surfaces define at least one indentation such that the surfaces exist in multiple planes. Each of the surfaces has an implanted region containing an ion species selected from the group consisting of C, N, H, F, He, Ar, B, As, P, Ge, Ga, Si, Zn, and Al. The implanted region is hydrophobic.

According to a first aspect of the invention, a method of implanting is provided. The method comprises applying a film to at least one surface of a template. This template is configured for printing. An ion species is directed toward the surface of the template. A material is printed on a workpiece using the template.

### BRIEF DESCRIPTION OF THE DRAWINGS

For a better understanding of the present disclosure, reference is made to the accompanying drawings, which are incorporated herein by reference and in which:

FIG. 1 is a cross-sectional view of printing using a template during a first step;

FIG. 2 is a cross-sectional view of printing using a template during a second step;

FIG. 3 is a cross-sectional view of a first embodiment of an implanted template;

FIG. 4 is a cross-sectional view of a second embodiment of an implanted template;

FIG. 5 is a cross-sectional view of a third embodiment of an implanted template;

FIG. 6 is a cross-sectional view of a fourth embodiment of an implanted template;

FIG. 7 is a first embodiment of implanting a template;

FIG. 8 is a second embodiment of implanting a template;

FIG. 9 is a third embodiment of implanting a template;

FIG. 10 is a fourth embodiment of implanting a template; and

FIG. 11 is a block diagram of a plasma processing apparatus having an insulating modifier

### DETAILED DESCRIPTION

The embodiments are described herein in connection with an ion implanter. Many different ion implantation systems or plasma processing systems may be used to perform these embodiments. Furthermore, while a template for printing is specifically disclosed, other items and substrates may benefit from the embodiments disclosed herein. The use of the word template is not meant to be limiting. The template may be a stamp or mold for printing or forming patterns on many different materials. Thus, the invention is not limited to the specific embodiments described below.

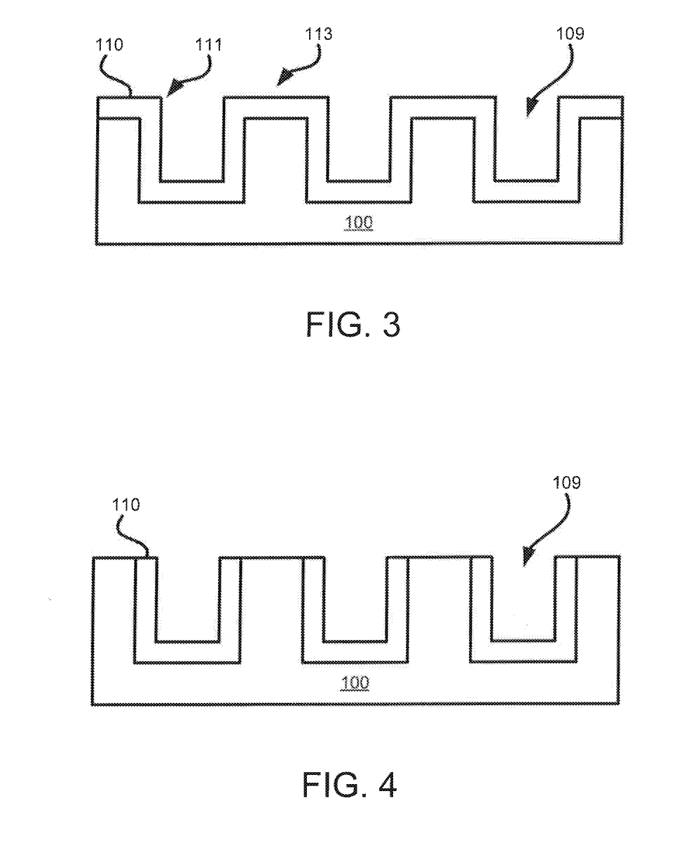

FIG. 3 is a cross-sectional view of a first embodiment of an implanted template. The template 100 is composed of silica and has multiple indentations 109. These indentations 109 have surfaces that exist in multiple planes, such as the horizontal or vertical plane as illustrated in FIG. 3. The silica may be a fused silica or quartz. In an alternate embodiment, the template 100 is composed of alumina, glass, stainless steel, silicon, or a polymer.

The template 100 material is generally hydrophilic. This template 100 has an implanted region 110. This implanted region 110 follows the contour of the template 100 and all the surfaces of the template 100 and indentations 109. The implanted region 110 may be implanted with ion species such as, for example, C, N, H, F, He, Ar, B, As, P, Ge, Ga, Si, Zn, Al, other noble gases, or other p-type or n-type dopants at a dose within the approximately 1E15 to 1E17 range. Of course, other ion species or doses also may be used and this list is not exclusive. These ion species may be generated from, for example, CH₄, H₂, NF₃, BF₃, CF₄, SF₆, N₂, or He.

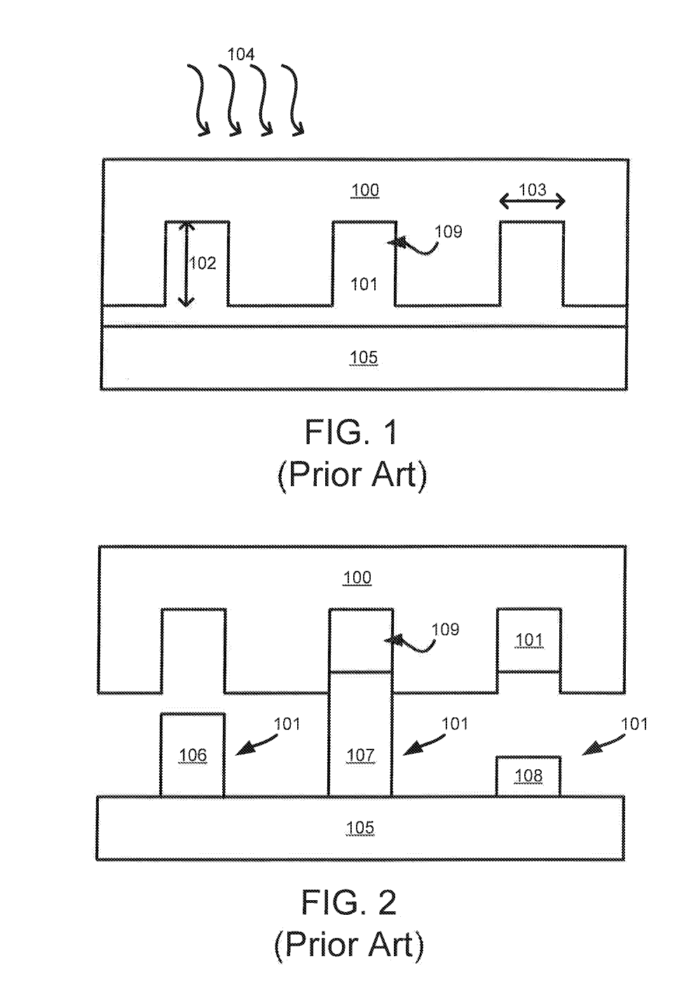

The implanted region 110 is generally hydrophobic, while the remainder of the template 100 is generally hydrophilic. The will reduce or prevent adhesion by a polymer used for printing with the template 100, such as the polymer 101 of FIGS. 1-2. The ion species that is implanted may in part affect the hydrophobicity. Certain energy levels or doses during implantation may modify the lattice structure of the template 100, which also may in part affect the hydrophobicity. Other mechanisms due to implant that affect the hydrophobicity may be possible.

The implanted region 110 will remain hydrophobic even if cleaned because the implanted region 110 is part of the template 100 instead of a coating on the surface of the template 100 that may be eroded or washed off. To maintain the hydrophobic state, at least a few monolayers of the template 100 are implanted to form the implanted region 110. The implanted region 110 may be less than approximately 50 nm in depth. Multiple implant steps on the same template may be needed in one instance to form the implanted region 110.

Release force between the implanted regions 110 of the template 100 and a polymer is lower than between the material of the template 100 and a polymer. Release force is the force needed to separate the polymer from the template 100. An improved release force means that the polymer has an increased probability of not sticking to the template 100 when the template 100 is withdrawn from a workpiece after the template is exposed to a wavelength of light. A lower release force increases the probability of accuracy in the pattern formed by the polymer or that the polymer will match the indentations 109 in the template 100.

The corners 111 of the indentations 109 are not chipped or eroded by the formation of the implanted region 110. Altering the shape of the indentations 109 may affect the patterns formed later with the polymer. Furthermore, surface roughness of the template may not be affected by the implantation. Defects to the template are managed or prevented using the implantation process. Implantation occurs at vacuum, so there are few particles to cause defects.

The extinction coefficient (k) value is not modified extensively by the formation of the implanted region 110. This k value refers to the extent the intensity of a beam of light is reduced. By maintaining the k value, then the polymer will set or harden as anticipated during printing. In one example, the k value was altered by less than approximately 15% through formation of the implanted region 110. The implant species used to form the implanted region 110 affects this k value. Furthermore, this k value is exposure wavelength dependent so depending on the wavelength used to harden the polymer a particular implant species is selected so as to not affect the absorption of the template. This is demonstrated using the following formula:

T=(1−r)exp(−4πkt/wavelength)

T is transmission, r is reflection, k is the extinction coefficient, t is the thickness of the template 100, and the wavelength represents the exposure wavelength. The ideal state is when k equals zero and the transmission is related only to the reflection loss. If the reflection loss is zero, then the transmission is proportional to the incident exposure. In one embodiment, the implantation is configured to not affect the transmission through a constant k value, but reflectivity suppression may occur. If transmission at a particular wavelength is affected, it is possible that the polymer may not harden correctly. Thus, the polymer may not form the desired pattern during printing.

Uniformity of the dose and depth implanted region 110 may be controlled. In one instance, uniformity of the dose and depth demonstrated less than approximately 10% variation across the template 100. If certain areas of the template 100 are implanted in a non-uniform manner or are not implanted at all, this may affect adhesion of the polymer. Furthermore, for certain species an implant that is too deep or at too high a dose may affect adhesion. A non-uniform implant may lead to the polymer adhering to the template in the areas with the non-uniform implant, such as an area with a lower dose or lower implant depth compared with the rest of the implanted region 110.

The implanted region 110 may densify the material of which the template 100 is composed. This densification is due to the material added to the lattice of the template 100 during implantation. The densification may affect hydrophobic or hydrophilic properties of the template 100.

The implanted region 110 also may improve the lifetime of the template 100. The template 100 has a limited lifetime due to, for example, failure of the material properties of the template 100, cracking or breaking of the template 100, or the polymer adhering in the indentations 109. By reducing or preventing adhesion of the polymer to the template 100 or in the indentations 109, then the lifetime of the template 100 may be improved. This may reduce production costs.

While the embodiment of FIG. 3 is illustrated as having an implanted region 110 that is uniform, in one particular embodiment the walls of the indentations 109 may receive a different dose or implant species than the top surface 113. The top surface 113 may receive little or no dose. This is because the polymer is shaped using the indentations 109 rather than the top surface 113 and there is little or no polymer disposed against the top surface 113 during printing. The polymer in the indentations 109 may primarily form the desired shape or pattern. FIG. 4 is a cross-sectional view of a second embodiment of an implanted template. In this embodiment, the walls of the indentations 109 have an implanted region 110, while the top surface 113 receives a low or no dose across the majority of its surface. Various implantation techniques, such as scanning during implant, focusing the ion species during implant of individual indentations 109, a stencil or shadow mask, or photoresist may be used to enable the embodiment illustrated in FIG. 4. The mask or photoresist may block implantation to the top surface 113. In another embodiment, different sides of the indentations 109 may receive a different dose or implant species.

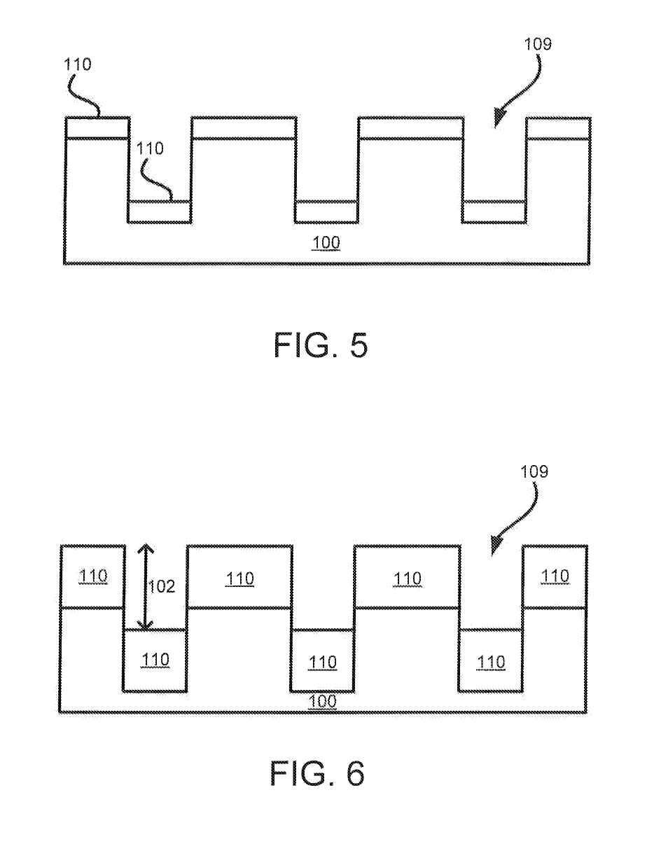

FIG. 5 is a cross-sectional view of a third embodiment of an implanted template. In this embodiment, a plurality of implanted regions 110 are formed. These implanted regions 110 may be formed by implanting the template 100 at an angle perpendicular to the surfaces that have the implanted regions 110. However, certain surfaces of the indentations 109 of the template 100 that a polymer may contact are not implanted. This embodiment may be sufficient to improve adhesion of a polymer to the template 100. However, this embodiment also may lead to adhesion of the polymer to the surfaces that are not implanted. Such a result may be desired for certain applications.

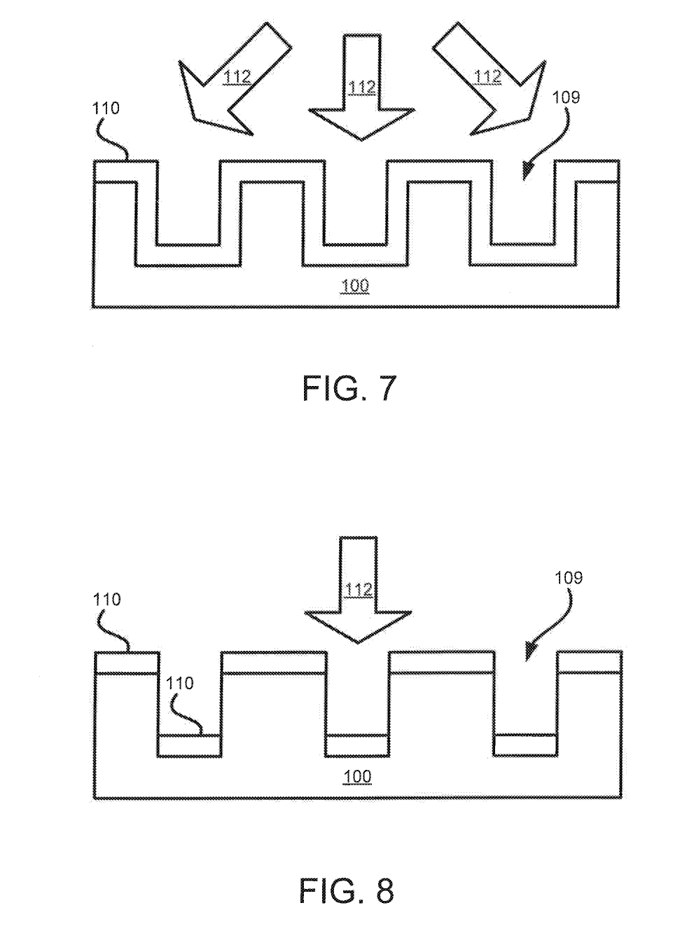

FIG. 6 is a cross-sectional view of a fourth embodiment of an implanted template. In this embodiment, a plurality of implanted regions 110 are formed by implanting the template 100 at an angle perpendicular to the surfaces that have the implanted regions 110. However, the energy of the ions that are implanted to form the implanted regions 110 is higher than that illustrated in FIG. 5. This leads to a larger implanted depth in the template 100. Thus, in this particular embodiment, the implanted regions 110 extend almost equal to the depth 102. In an alternate embodiment, the implanted regions 110 extend beyond the depth 102 and may overlap with the other implanted regions 110.

FIG. 7 is a first embodiment of implanting a template. In this embodiment, the ion species 112 is implanted using an ion spread or at a plurality of different angles. This may be performed simultaneously or sequentially using multiple implant steps. The ion spread or multiple angles produce an implant region 110 on every surface of the indentations 109 of the template 100. A plasma doping tool or plasma processing apparatus with an insulating modifier, for example, may be used to produce these angles. A beam-line ion implanter also may be used. For a beam-line ion implanter, the angle between the template 100 and the ion species 112 is changed and multiple implant steps are performed. A platen on which the template 100 is disposed may be translated or rotated or the ion beam containing the ion beams 112 may be directed to form a different implant angle.

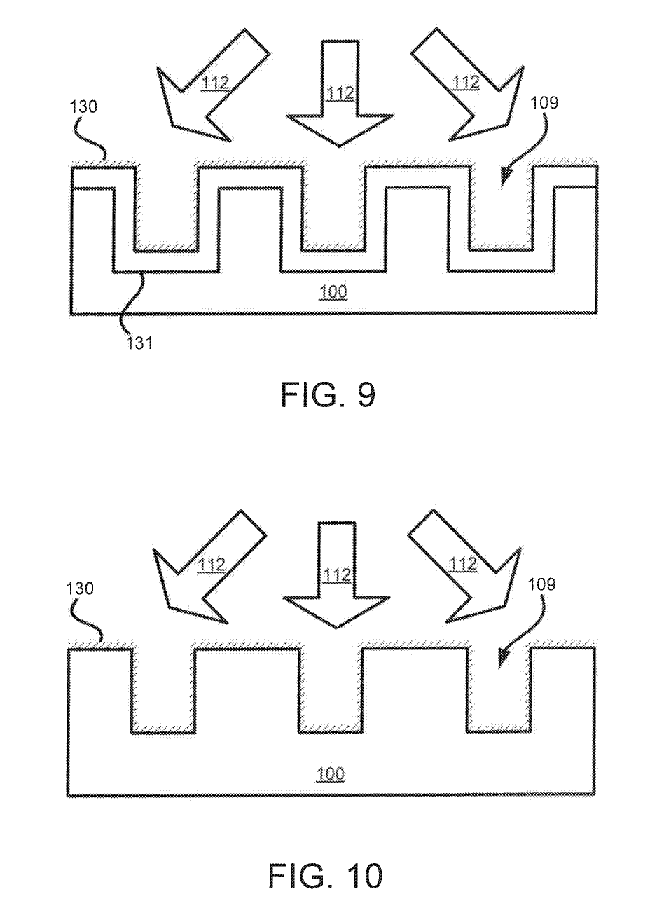

FIG. 8 is a second embodiment of implanting a template. In this particular embodiment, the ion species 112 is implanted at a single angle perpendicular to a surface of the template 100. This results in multiple implanted regions 110 as illustrated in FIGS. 5-6.

In yet another embodiment, a film containing a species, such as a dopant, is applied to the template 100. FIG. 9 is a third embodiment of implanting a template. A film 130 is applied to the template 100 (illustrated by the shaded region). This film 130 may contain a dopant and may be deposited on at least one surface of the indentations 109. In an alternate embodiment, the film 130 is selectively applied to the template 100 such that only certain regions, such as the surfaces of the indentations 109, are covered.

The ion species 112 drive in or knock in the species from the film 130 into the lattice of the template 100 to form the doped region 131. The film 130 may be CFₓ or an n-type or p-type dopant-containing molecule. The ion species 112 may drive in or knock in the species from the film 130 a few nanometers or to other depths. This ion species 112 may be, for example, Ar, Ne, or Xe. The ion species 112 is illustrated in FIG. 9 as using an ion spread or a plurality of different angles, but in an alternate embodiment the ion species 112 is implanted at a single angle perpendicular to a surface of the template 100 similar to that illustrated in FIG. 8. The film 130 may be removed in some embodiments after the implantation step or the process illustrated in FIG. 9 may be repeated.

FIG. 10 is a fourth embodiment of implanting a template. In this embodiment, the ion species 112 may be used to harden the film 130 applied to the template 100. This increases the number of cycles the film 130 may be used before replacement and, by use of hardening, the film 130 is less likely to be removed during cleaning steps. The ion species 112 is illustrated in FIG. 10 as using an ion spread or a plurality of different angles, but in an alternate embodiment the ion species 112 is implanted at a single angle perpendicular to a surface of the template 100 similar to that illustrated in FIG. 8.

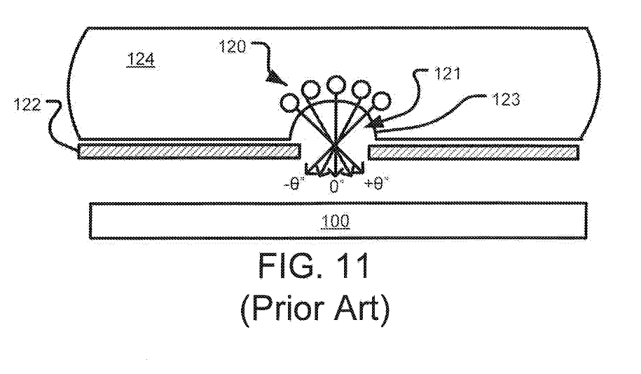

FIG. 11 is a block diagram of a plasma processing apparatus having an insulating modifier. The plasma 124 is generated as is known in the art and is generally a quasi-neutral collection of positively-charged molecular or atomic ions and negatively-charged electrons. In a system containing the plasma 124, ions 120 from the plasma 124 are attracted toward a template 100, which is illustrated as flat in this embodiment for simplicity but may contain the indentations illustrated elsewhere. The plasma 124 is bounded by a region proximate the template 100 referred to as a plasma sheath 121. The plasma sheath 121 is a region that has fewer electrons than the plasma 124. Hence, the differences between the negative and positive charges cause a sheath potential in the plasma sheath 121. The light emission from this plasma sheath 121 is less intense than the plasma 124 because fewer electrons are present and, hence, few excitation-relaxation collisions occur. Thus, the plasma sheath 121 is sometimes referred to as “dark space.”

The insulating modifier 122 is configured to modify an electric field within the plasma sheath 121 to control a shape of a boundary 123 between the plasma 124 and the plasma sheath 121. Accordingly, ions 120 that are attracted from the plasma 124 across the plasma sheath 121 may strike the template 100 at a large range of incident angles or trajectories, such as, for example, between +θ° and −θ° centered around 0°. This is one example of implanting using an ion spread or a plurality of different angles. The distance between the insulating modifier 122 and the template 100 or the size of the aperture in the insulating modifier 122 that the ions 120 pass through may affect this range of incident angles. By adjusting these variables, the ions 120 may be focused on a particular point on the template 100, such as the indentations 109 illustrated in FIG. 4, or widened to implant the entire template 100 with a wide ion spread. This insulating modifier 122 may be referred to as, for example, a focusing plate or sheath engineering plate. While an insulating modifier 122 is specifically disclosed, semiconductors or conductors may be used instead of insulators.

Ions 120 may be attracted from the plasma 124 across the plasma sheath 121 by different mechanisms. In one instance, the template 100 is biased to attract ions 120 from the plasma 124 across the plasma sheath 121. In another instance, a plasma source that generates the plasma 124 and walls surrounding the plasma 124 are biased positively and the template 100 may be grounded. The biasing may be pulsed in one particular embodiment. In yet another instance, electric or magnetic fields are used to attract ions 120 from the plasma 124 toward the template 100. When the template 100 is biased, for example, the ions 120 are attracted across the plasma sheath 121 through the aperture in the insulating modifier 122.

The embodiment of FIG. 11 may provide benefits to implanting the template 100. For example, the range of incident angles may be controlled or specific areas of the template 100 may be implanted while other areas are not. Scanning the template 100 when the ions 120 are not implanted may enable these selective or patterned implants in one instance. Use of the insulating modifier 122 may be beneficial, for example, to implant the indentations of a template without implanting other surfaces of the template. Furthermore, if all surfaces of an indentation in a template are treated simultaneously using the large range of incident angles or trajectories, this may reduce processing time to implant a template.

The template described herein may be used for printing in semiconductor applications such as logic, dynamic random access memory (DRAM), flash memory, or analog devices. Of course, other applications are possible. For example, the workpiece being printed also may be bit patterned media such as a computer hard drive. The workpiece being printed also may be a micro mirror or a microelectromechanical systems (MEMS) device, for example. Of course, other applications will be apparent to those skilled in the art. If adhesion is reduced, it may be possible to print or form smaller structures or patterns of the polymer using the template.

The template described herein also may be used for biomedical applications. The indentations in the template may be used to produce a series of channels on a workpiece with walls composed of the polymer. The channels may be used, for example, to allow the flow of blood or other body fluids for testing or diagnostics. “Microfluidics” is one example of such a process.

The template also may be used with workpieces that are organic light emitting diodes (organic LED or OLED). While such a template may have indentations, in other instances the template may not have indentations. Instead, the template may be a flat sheet used to make a uniform polymer layer of a certain thickness. Such a template may still benefit from a reduction in adhesion with the polymer. The hydrophobic surface of the template may allow the polymer to spread more easily and not have non-uniformities caused by sticking to the template. Of course, one skilled in the art will recognize that many different template shapes are possible and may benefit from the embodiments described herein.

The template may be used to print other materials than a polymer. For example, the template may be used to print or press graphite into particular shapes or patterns. In another instance, a master mold is formed using the implanted template and this master mold is used multiple times. Thus, polymers are merely one example of a material that is printed.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method of implanting comprising:
implanting at least one surface of a template with an ion species, said template configured for printing; and
printing a material on a workpiece using said template.

2. The method of claim 1, wherein said at least one surface is hydrophilic prior to said implanting and is hydrophobic after said implanting.

3. The method of claim 1, wherein said ion species is selected from the group consisting of C, N, H, F, He, Ar, B, As, P, Ge, Ga, Si, Zn, and Al.

4. The method of claim 1, wherein said template is composed of silica.

5. The method of claim 1, wherein said template comprises a plurality of surfaces that define an indentation in said template, and wherein said implanting is into all of said plurality of surfaces around said indentation.

6. The method of claim 1, further comprising densifying said surface.

7. The method of claim 1, wherein said implanting comprises using an ion spread of said ion species.

8. The method of claim 1, wherein said implanting comprises simultaneously implanting said ion species at a plurality of angles with respect to said template.

9. The method of claim 1, further comprising modifying a plasma sheath of said ion species to spread said ion species into a plurality of trajectories.

10. The method of claim 1, wherein said material is a polymer and said printing comprises dispensing said polymer on said workpiece, lowering said template onto said polymer, applying a wavelength of light to said template, and removing said template from said polymer.

11. The method of claim 1, wherein said workpiece comprises one of a bit-patterned media, an organic LED, a biomedical chip, a microfluidic channel, a MEMS device, and a semiconductor device.

12. A template apparatus comprising:
a template composed of silica having a plurality of surfaces, said plurality of surfaces defining at least one indentation such that said plurality of surfaces exist in multiple planes, wherein each of said plurality of surfaces has an implanted region containing an ion species selected from the group consisting of C, N, H, F, He, Ar, B, As, P, Ge, Ga, Si, Zn, and Al, and wherein said implanted region is hydrophobic.

13. The template apparatus of claim 12, wherein said silica below said implanted region is hydrophilic.

14. The template apparatus of claim 12, wherein said indentation is configured to match a pattern printed on a workpiece using a polymer.

15. A method of implanting comprising:
applying a film to at least one surface of a template, said template configured for printing;
directing an ion species toward said at least one surface of said template; and
printing a material on a workpiece using said template.

16. The method of claim 15, wherein said ion species is selected from the group consisting of C, N, H, F, He, Ar, B, As, P, Ge, Ga, Si, Zn, and Al.

17. The method of claim 15, further comprising hardening said film.

18. The method of claim 15, further comprising knocking in a species from said film into a lattice of said template using said ion species.

19. The method of claim 15, wherein said implanting comprises simultaneously implanting said ion species at a plurality of angles with respect to said template.

20. The method of claim 15, wherein said material is a polymer and said printing comprises dispensing said polymer on said workpiece, lowering said template onto said polymer, applying a wavelength of light to said template, and removing said template from said polymer.
